(19) United States
(12) Patent Application Publication
(10) Pub. No.: US 2008/0268617 A1
(43) Pub. Date: Oct. 30, 2008

(54) METHODS FOR SUBSTRATE SURFACE CLEANING SUITABLE FOR FABRICATING SILICON-ON-INSULATOR STRUCTURES

(75) Inventors: Randhir P. S. Thakur, San Jose, CA (US); Stephen Moffatt, (US); Per-Ove Hansson, San Jose, CA (US); Steve Ghanayem, Los Altos, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/463,429

(22) Filed: Aug. 9, 2006

(51) Int. Cl. H01L 21/30

(52) U.S. Cl. 438/458; 438/455; 257/E21.211

(57) ABSTRACT

Methods for cleaning substrate surfaces utilized in SOI technology are provided. In one embodiment, the method for cleaning substrate surfaces includes providing a first substrate and a second substrate, wherein the first substrate has a silicon oxide layer formed thereon and a cleavage plane defined therein, performing a wet cleaning process on the surfaces of the first substrate and the second substrate, and bonding the cleaned silicon oxide layer to the cleaned surface of the second substrate.

### BACKGROUND OF THE INVENTION

1. Field of the Invention

Embodiments of the invention generally relate to the field of semiconductor manufacturing processes and devices, more particular, to methods for substrate surface cleaning suitable for fabricating in silicon-on-insulator (SOI) structures.

2. Description of the Related Art

Semiconductor circuit fabrication is evolving to meet ever increasing demands for higher switching speeds and lower power consumption. A higher device switching speed at a given power level is desired for applications requiring large computational power. In contrast, a lower power consumption level at a given switching speed is desired for mobile applications. Increased device switching speed may be attained by reducing the junction capacitance. Reduced power consumption may be attained by reducing parasitic leakage current from each device to the substrate. Both reduced junction capacitance and reduced parasitic leakage current is attained by forming devices on multiple silicon islands formed on an insulating (e.g., silicon oxide) layer on the semiconductor substrate. Each island is electrically insulated from all other islands by the insulating layer. Such a structure is called a silicon-on-insulator (SOI) structure.

SOI structures may be formed in a layer transfer process in which a crystalline silicon wafer is bonded to the top of a silicon oxide layer previously formed on another crystalline silicon wafer. FIGS. 1A-G depict an exemplary conventional method for fabricating SOI structures on a substrate. A donor substrate 102 and a handle substrate 104 are utilized to form SOI structures, as shown in FIG. 1A. A thermal oxidation process may be performed to form a silicon oxide layer 106 on the surface and/or the periphery of the donor substrate 102, as shown in FIG. 1B. An ion implantation process may be performed to implant ions, e.g., hydrogen ions, into the donor substrate 102, thereby forming a cleavage plane 108 below the surface of the donor substrate 102, as shown in FIG. 1C. Subsequently, an O₂ plasma surface treatment process may be performed to form activated surfaces 112, 114 on both the donor substrate 102 and handle substrate 104, as shown in FIG. 1D, promote the bonding energy at the interface. The activated surfaces 112, 114 are abutted together by flipping the silicon oxide surface the donor substrate 102 over to adhere to the surface 114 of the handle substrate 104, as shown in FIG. 1E. The activated surface 112 of the donor substrate 102 is bonded to the activated surface 114 on the handle substrate 104, as shown in FIG. 1F. In a final step, the donor substrate 102 is split along the cleavage plane 108, leaving a portion of silicon layer 110 and the silicon oxide layer 106 adhered to the handle substrate 104, as shown in FIG. 1G. The silicon layer 110 and the silicon oxide layer 106 bonded on the handle substrate 104 form the SOI structure.

During substrate bonding process, several problems have been observed. For example, interface surface particles, surface imperfections, contaminants, or air trapped at the substrate interface may result in poor adhesion and bonding failure between the donor and handle substrates. Poor adhesion and bonding failure at the interface may affect the mechanical strength and electric behavior of the devices built on the substrate, thereby causing poor device performance and/or failure, along with adversely affecting device integration.

Therefore, there is a need to improve substrate surface cleaning efficiency utilized in SOI fabrication.

### SUMMARY OF THE INVENTION

Methods for cleaning substrate surface that promote bonding between substrates are provided. The methods are particularly useful for SOI fabrication. In one embodiment, a method for cleaning substrate surfaces includes providing a first substrate and a second substrate, wherein the first substrate has a silicon oxide layer formed thereon and a cleavage plane defined therein, performing a wet cleaning process on a surface of the silicon oxide layer on the first substrate and a surface of the second substrate, and bonding the cleaned silicon oxide layer to the cleaned surface of the second substrate.

In another embodiment, a method for cleaning substrate surfaces includes providing a first substrate and a second substrate, wherein the first substrate has a silicon oxide layer formed thereon and a cleavage plane defined therein, removing particles and/or contaminants from a surface of the first substrate and a surface of the second substrate by a wet cleaning process, activating the cleaned surfaces of the first and the second substrate, and bonding the silicon oxide layer disposed on the first substrate to the activated surface of the second substrate.

In yet another embodiment, a method for cleaning substrate surfaces includes providing a first substrate and a second substrate, wherein the first substrate has a silicon oxide layer formed thereon and a cleavage plane defined therein, performing a wet cleaning process on a surface of the silicon oxide layer and a surface of the second substrate by exposure to a solution including NH₄OH, H₂O₂ and H₂O, activating the cleaned surfaces of the first and the second substrate, bonding the silicon oxide surface to the activated surface of the second substrate, and splitting the first substrate along the cleavage plane.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1G depict an exemplary embodiment of a conventional process for SOI structures manufacture;

FIG. 2 depict one embodiment of a single substrate wet clean tool suitable for practice the present invention;

FIG. 3 depicts a process diagram illustrating a method for manufacturing SOI structures according to one embodiment of the present invention;

FIGS. 4A-4G depict cross section views of SOI structures formed on a substrate according to the method as described in FIG. 3; and

FIGS. 5A-5F depict a surface bonding mechanism according to one embodiment of the present invention.

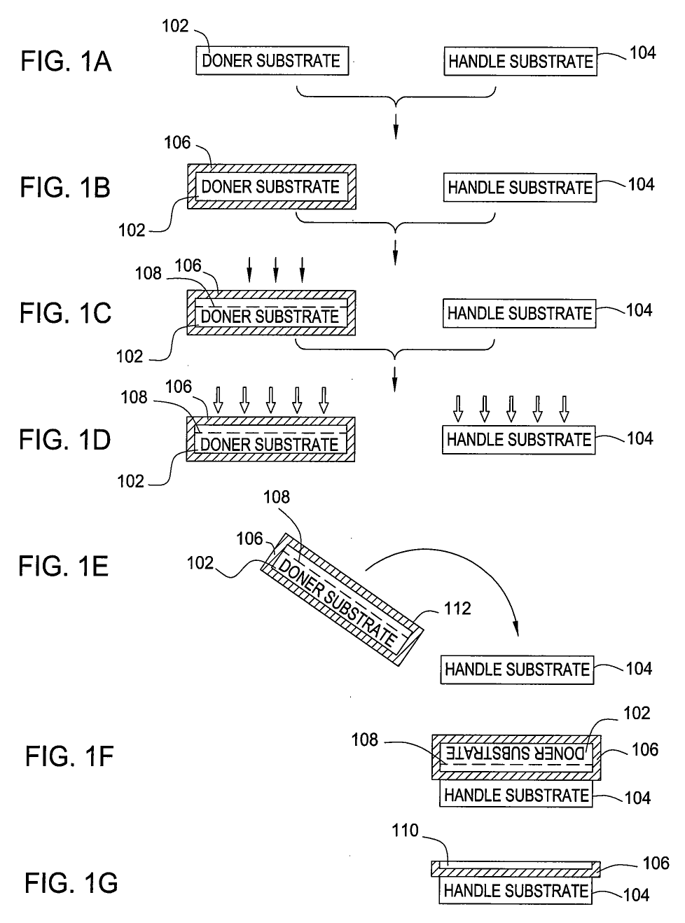

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for substrate surface cleaning that promote interface bonding energy between substrates which may be utilized in SOI fabrication. In one embodiment, the substrate surface cleaning process includes a RCA cleaning method including a Standard Clean first (SC1) operation using a solution including NH₄OH/H₂O₂/H₂O followed by an optional Standard Clean second (SC2) using a solution including HCl/H₂O₂/H₂O to remove particles, organic impurities, such as hydrocarbon compounds, and metal contaminants and/or particles. The cleaning process removes the native oxide and particles on the substrate surfaces, thereby improving bonding strength and reducing voids trapped at the interface. Additionally, the cleaning process provides a fresh silicon and/or silicon oxide surface to promote the bonding strength, thereby resulting in an uniform bonding surface and a strong bonding adhesion.

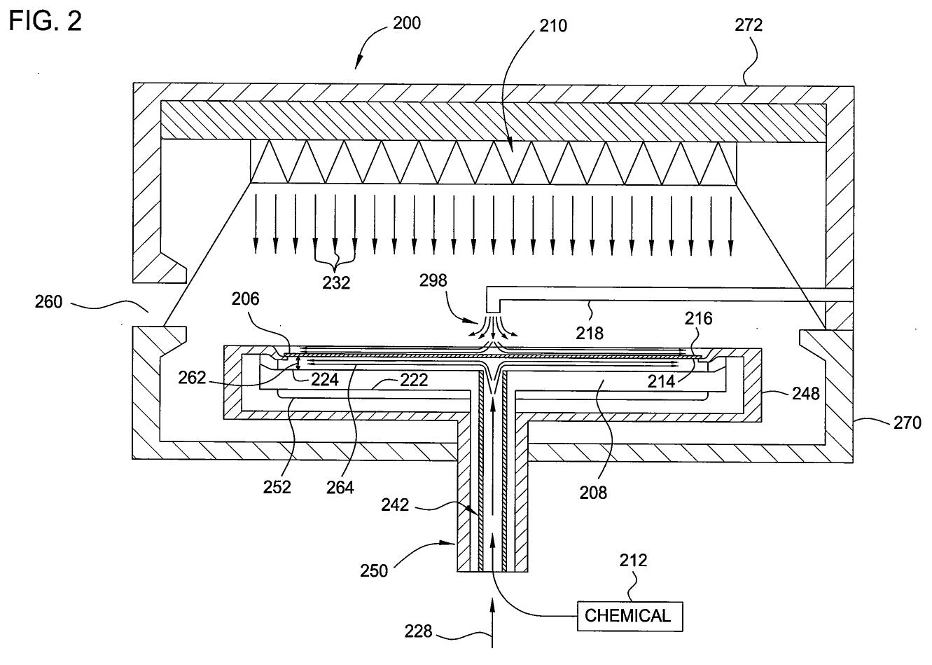

FIG. 2 depicts a schematic cross-section view of one embodiment of a single-substrate clean chamber 200 that may be utilized to practice the present invention. One example of a single-substrate clean system is an OASIS CLEAN™ system available from Applied Materials, Inc. of Santa Clara, Calif. It is contemplated that the cleaning process may be performed in other suitable cleaning systems, such as a wet bench system.

The single-substrate clean chamber 200 includes a rotatable substrate holding bracket 248 adapted to receive a substrate 206. A robot arm (not shown) may enter into the chamber 200 through a slit valve 260 to facilitate the movement of the substrate 206 from the chamber 200. The robot arm places the substrate 206 onto the bracket 248 in an initial position. The substrate 206 is subsequently lowered to a process position, as illustrated in FIG. 2. The process position maintains the substrate 206 in a position parallel to and space-apart from a top surface 224 of a circular plate 208, thereby defining a gap 262 between the circular plate 208 and a bottom side 214 of the substrate 206. In one embodiment, the gap 262 is controlled at a distance between about 0.1 millimeter (mm) and about 5 mm, such as about 3 mm.

A transducer 252 is attached to a bottom side 222 of the circular plate 208 adapted to create acoustic or sonic waves directed towards the surface of the substrate 206, e.g., in a direction perpendicular to the surface of the substrate 206, to enhance cleaning efficiency. In one embodiment, the transducer 252 generates megasonic waves in a frequency range above 350 kHz. The frequency of the transducer 252 may be varied based on materials and thickness of the substrate 206 to effectively assist particle removal from the substrate 206. The transducer 252 covers substantially the entire bottom surface 222 of the circular plate 208, such as covering the bottom surface 222 of the circular plate 208 greater than 80 percent. Alternatively, one or more transducers 252, such as four transducers, may be utilized to couple to the bottom surface 222 of the circular plate 208 in a quadrant formation.

A fluid feed port 228 is formed in a conduit 250 coupled to a bottom 270 of the chamber 200 to supply liquid 264 from a chemical source 212 to the gap 262 defined between the circular plate 208 and the backside of the substrate 206. In one embodiment, the liquid 264 may include diluted HF or deionized water (DI-H₂O), cleaning solution, such as SC1 and/or SC2 cleaning solution, or other suitable cleaning solution utilized to clean the substrate 206. The liquid 264 may act as a carrier for transferring megasonic energy from the transducer 252 to the substrate 206 to assist the particle removing from the substrate, thereby increasing cleaning efficiency. Furthermore, the liquid 264 may be controlled at a desired temperature, allowing the liquid 264 to carry heat to or from the substrate 206, thereby maintaining the substrate 206 at a predetermined temperature.

A filter 210 is disposed on a top 272 of the chamber 200 to clean air 232 flowing into the process chamber 200 which is directed at the top surface 216 of the substrate 206. At least a nozzle 218 is positioned above the substrate 206 to direct flow 298 of a cleaning chemical, such as gas, vapor or a liquid, to contact and clean the substrate 206. In operation, cleaning chemicals, such as diluted HF or deionized water (DI-H₂O), cleaning solution, such as SC1 and/or SC2 cleaning solution, is dispensed to the substrate 206 at a flow rate sufficient to cover the entire surface of the substrate 206 upon the rotation of the substrate holding bracket 248. In one embodiment, the top side 216 and bottom side 214 of the substrate 206 disposed on the bracket 248 may be cleaned independently to provide better control of the cleaning efficiency based on the substrate materials and properties. The substrate holding bracket 248 may be rotated at a rotation speed between about 1000 rpm and about 3000 rpm at a flow rate of cleaning solution supplied from the nozzle 218 between about 0.5 liter per minute (I/min) and about 2 liter per minute.

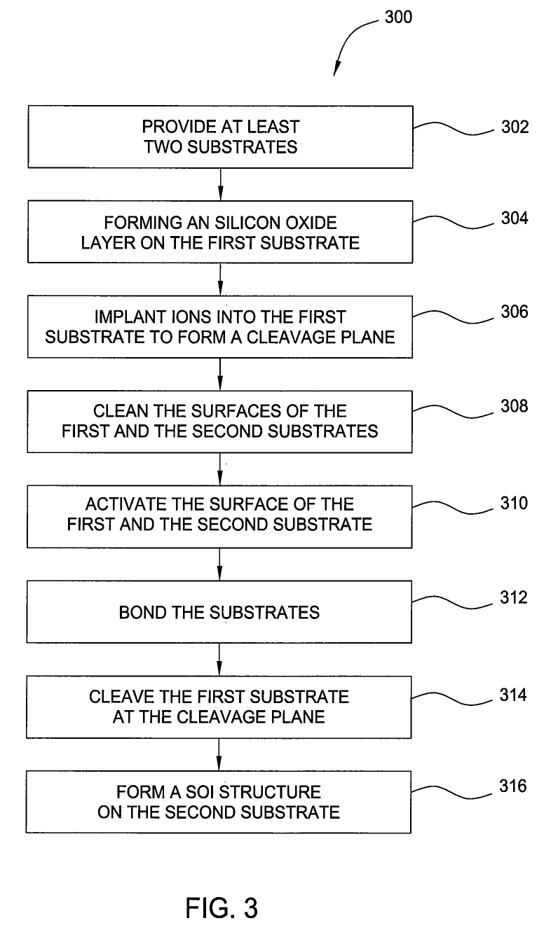

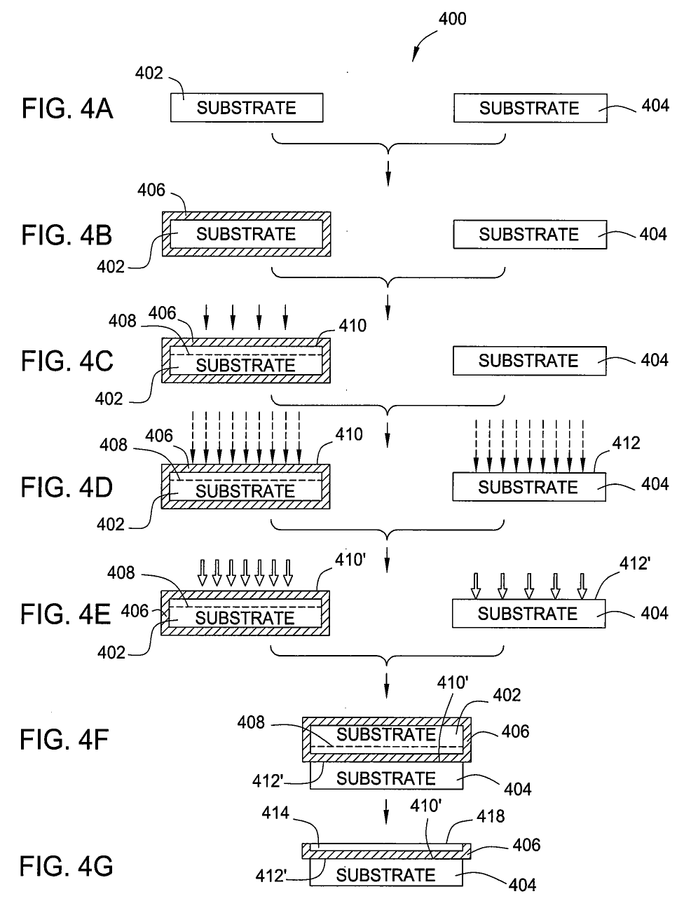

FIG. 3 depicts a process flow diagram of a method 300 for cleaning substrate surfaces suitable for SOI fabrication. FIGS. 4A-G are schematic cross-sectional views illustrating different stages of a SOI fabrication process according to the method 300.

The method 300 begins at step 302 by providing at least two substrates 402, 404 (e.g., a pair) utilized to form SOI structures, as shown in FIG. 4A. In one embodiment, the first substrate 402 and the second substrate 404 may be a material such as crystalline silicon (e.g., Si<100> or Si<111>), strained silicon, silicon germanium, doped or undoped polysilicon, doped or undoped silicon wafers, doped silicon, germanium, gallium arsenide, gallium nitride, glass, and sapphire. The substrates 402, 404 may have various dimensions, such as 200 mm or 300 mm diameter wafers, as well as, rectangular or square panes. Unless otherwise noted, embodiments and examples described herein are conducted on substrates with a 200 mm or 300 mm diameter.

At step 304, a thermal oxidation process is performed on the first substrate 402 to oxidize the surface and periphery of the first substrate 402, forming a silicon oxide layer 406 thereon. The silicon oxide layer 406 may have a thickness at between about 500 Å and about 5000 Å, such as between about 1000 Å and about 2000 Å.

At step 306, a high energy cleavage ion implantation step is performed in which an ion species, such as hydrogen, is implanted to a uniform depth below the surface 416 to define a cleavage plane 408 within the first substrate 402, as shown in FIG. 4C. Within the cleavage plane 408, the ions implanted at step 306 creates damaged atomic bonds in the silicon crystal lattice, rendering the substrate susceptible to separation along the cleavage plane 108, as will be exploited later in the fabrication sequence described further below. In one embodiment, the cleavage plane 408 may be formed between about 3000 Å and about 5000 Å below the top surface 416 of the silicon oxide layer 406, or between about 1000 Å and about 3000 Å below the surface 410 of the substrate 402. The plasma immersion ion implantation process may be performed in a plasma immersion ion implantation reactor. One example of the plasma immersion ion implantation reactor may include P3i® reactors, available from Applied Materials, Inc. The plasma immersion ion implantation process is disclosed in detail by U.S. Patent Publication No. US 2005/0,070,073, published Mar. 31, 2005 to Al-bayati entitled “SILICON-ON-INSULATOR WAFER TRANSFER METHOD USING SURFACE ACTIVATION PLASMA IMMERSION ION IMPLANTATION FOR WAFER-TO-WAFER ADHESION ENCHANCEMENT” and is herein incorporated by reference.

At step 308, a cleaning process is utilized to clean and activate the surfaces of the first and second substrates 402, 404, as shown in FIG. 4D. The cleaning process cleans and slightly etches the substrate surface, thereby removing the particle and/or surface contaminants on the substrate surface. The cleaning process may be performed in the chamber 200 as described in FIG. 2. It is contemplated that the cleaning process may be performed in other cleaning tools, including those from other manufacturers.

The cleaning process is performed by a RCA cleaning process that includes a SC1 clean followed by an optional SC2 clean. In one embodiment, the SC1 cleaning solution includes a mixture of ammonium hydroxide (NH₄OH), hydrogen peroxide (H₂O₂), and de-ionized water (H₂O). The ammonium hydroxide (NH₄OH), hydrogen peroxide (H₂O₂), and de-ionized water (H₂O) are mixed as the SC1 solution at a predetermined dilution ratio between about 5:1:1 and about 1000:1:1. The ratio between the ammonium hydroxide (NH₄OH) and hydrogen peroxide (H₂O₂) may be controlled at between about 0.05:1 and about 5:1. Alternatively, the hydrogen peroxide (H₂O₂) may be optionally used. The ammonium hydroxide (NH₄OH) solution prepared for mixing the SC1 solution is formed by a solution containing between about 25 and about 30 weight percentage (w/w) of NH₃ to de-ionized water. The hydrogen peroxide (H₂O₂) solution prepared for mixing the SC1 solution is formed by a solution containing between about 30 and about 35 weight percentage (w/w) of H₂O₂ to de-ionized water. The pH level of the SC1 solution is controlled at between about 9 and about 12.

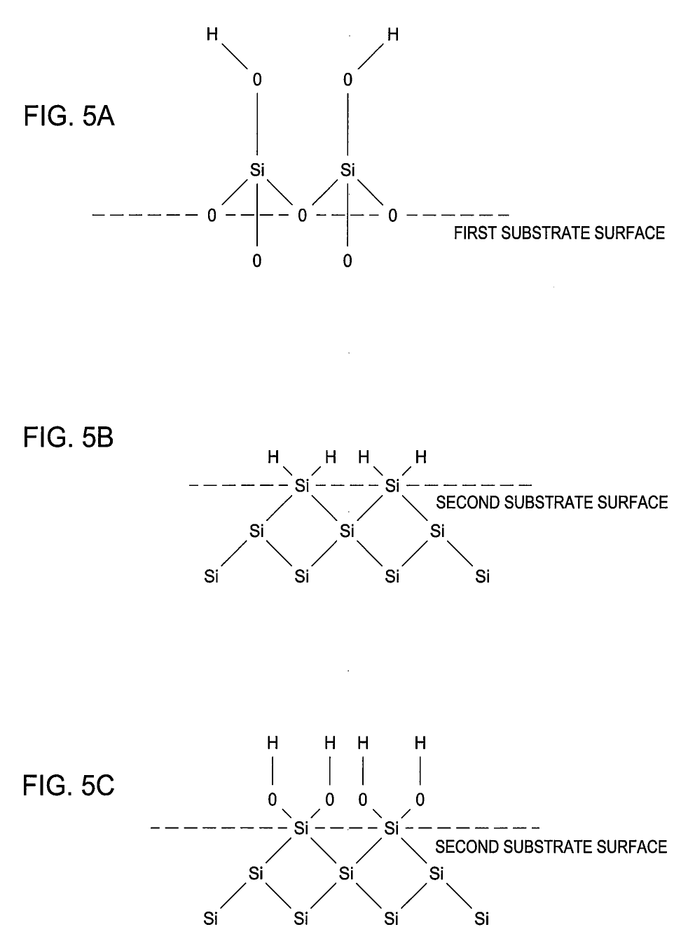

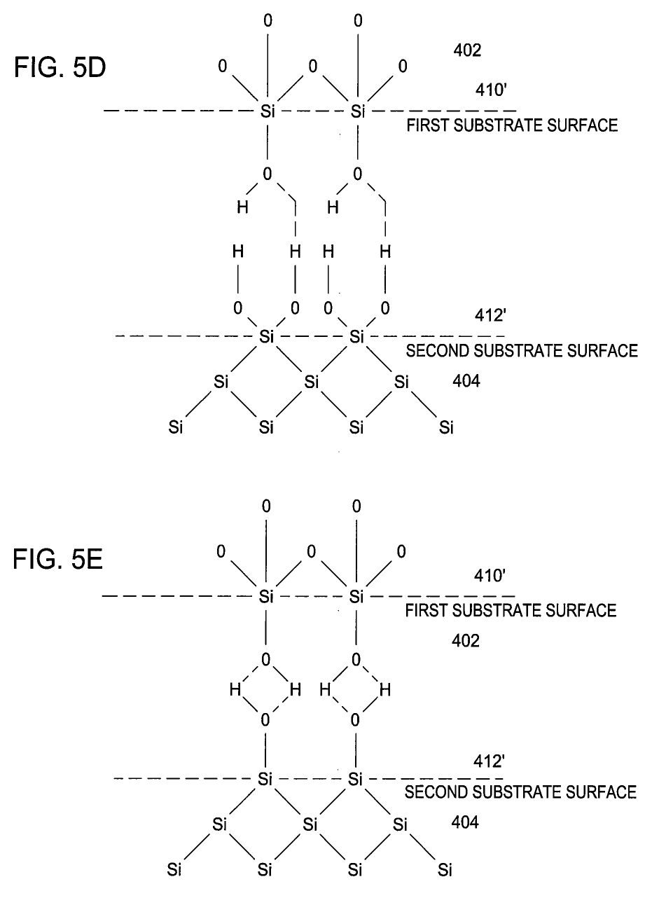

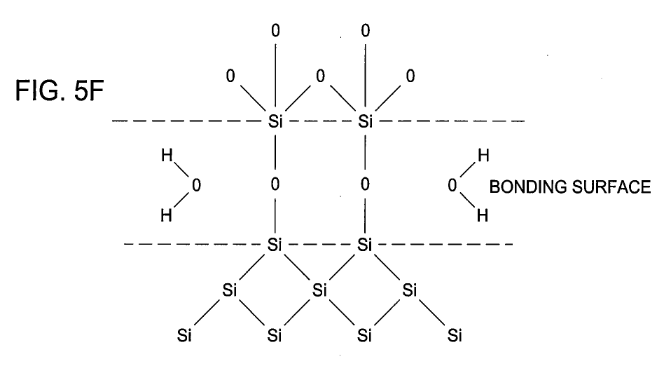

NH₄OH and H₂O₂ compound in SC1 solution simultaneously etch and lift the surfaces 410, 412 of the substrates 402, 404 to remove the particles, contaminants, and organic compounds. The surfaces 410, 412 are lifted and oxidized by H₂O₂ and subsequently slightly etched by NH₄OH, thereby undercutting and removing particles and contaminants on the substrate surfaces 410, 412. The particles and/or contaminants on the substrate surfaces 410, 412 react with NH₄OH, forming silica dissolved in the SC1 solution. NH₄OH in the SC1 solution provides the solution at a high pH level, such as about 9-12, so that the particles in the solution and the substrate surface maintain a negative charge, providing a mutually repulsive electrostatic force that keeps particles entrained in the solution, and thereby preventing particles from redepositing on the surfaces of the substrates. The NH₄OH in the SC1 solution also leaves the substrate surfaces 410, 412 in a hydrophilic state, as shown in FIG. 5A-B, which provides a better surface state for the subsequent bonding process. Acoustic energy is may be used to enhance the particle removal efficiency.

In another embodiment, a chelating agent and a surfactant may be added into the SC1 solution to improve cleaning efficiency. Suitable examples of chelating agent include polyacrylates, carbonates, phosphonates, gluconates, ethylenediaminetetraacetic acid (EDTA), N,N′-bis(2-hydroxyphenyl)ethylenediiminodiacetic acid (HPED), triethylenetetranitrilohexaaxtic (TTHA), desferriferioxamin B, N,N′,N″-tris[2-(N-hydroxycarbonyl)ethyl]-1,3,5-benzenetricarboxamide (BAMTPH) and ethylenediaminediorthohydroxyphenylacetic acid (EDDHA). The chelating agent is added to the SC1 solution at a concentration of between about 1 ppm and about 400 ppm. The chelating agent has negatively charged ions called ligands that bind with free metal impurities and ions and forms a combined complex solution dissolved in the SC1 solution, thereby removing the impurities from the substrate surfaces and into the SC1 solution.

The surfactant added in the SC1 solution prevents reattachment or redeposition of particles on the substrate surfaces after the particles have been dislodged from the substrates. Surfactants include long hydrocarbon chains that contain a hydrophilic (polar water soluble group) and a hydrophobic group (a non-polar water insoluble group). The surfactants have non-polar groups that attach to particles on the substrate surfaces 410, 412. The polar group of the surfactants pulls the particles away from the substrate surface 410, 412 and dissolves the particles into the SC1 solution. The particles bound by the surfactants are repelled electrostatically from the surfaces 410, 412 of the substrates 402, 404, thereby assisting in the particle removal. The surfactants added in the SC1 solution may be non-ionic, anionic, or a mixture of non-ionic and anionic compounds. Suitable examples of surfactants include polyoxyethylene butylphenyl ether, polyoxyethylene alkylphenyl sulfate, or MCX-SD2000 solution, commercially available from Mitsubishi Chemical Corporation of Tokyo, Japan.

In operation, the SC1 solution is supplied to the substrate surfaces 410, 412. The substrates 402, 404 are rotated at a speed between about 500 rpm and about 300 rpm to allow the SC1 solution to cover the entire surfaces 410, 412 of the substrate 402, 404. Alternatively or in addition, SC1 solution may be supplied to the bottom side of the substrates 402, 404 to clean the backside of the substrates. The particles on the backside of the substrates 402, 404 may also be removed by de-ionized water. The cleaning process time is maintained at between about 5 seconds to about 500 seconds, such as between about 30 seconds to about 180 seconds.

After the substrate surfaces 410, 412 have been cleaned by the SC1 solution, the SC2 solution may be optionally supplied to the cleaning chamber 200 to further clean the substrate surfaces 410, 412. The SC2 solution may include hydrochloric acid (HCl), hydrogen peroxide (H₂O₂), and de-ionized water (H₂O). The HCl in the SC2 solution is used to remove the metallic ions on the substrate surfaces 410, 412. As the chelating agent added in the SC1 solution also promotes the removal of the metallic ions and contaminants from the substrate surfaces, use of the SC2 solution is optional. A de-ionized water rinse process may be used between the SC1 cleaning and SC2 cleaning to prevent the cleaning solutions from reacting on the substrate surfaces.

In one embodiment, the ratio of the hydrochloric acid (HCl), hydrogen peroxide (H₂O₂), and de-ionized water (H₂O) in the SC2 solution may be between about 1:1:2 and about 1:1:10, such as about 1:1:5. The SC2 cleaning process may be performed at between about 5 seconds to about 15 minutes, such as between about 8 minutes and about 10 minutes.

The etched and/or activated surfaces 410, 412 resulting from the SC1 and/or SC2 cleaning process at step 308 creates a slight surface microroughness and good cleanness, thereby opening lattice sites which makes the lattice sites available to form covalent bonds with lattice sites in the other surface. Also, the etched and/or activated surfaces 410, 412 have slightly rougher surface compared to the unetched surface, providing better occlusion on the contact surfaces to securely adhere to each other, thereby enhancing the bonding energy therebetween.

After the SC2 cleaning process, the slightly acid SC2 solution may provide hydrogen ions that attach on the substrate surfaces 410, 412, thereby creating a hydrophilic state on the surface of the silicon oxide layer 406 of the substrate 402, as shown in FIG. 5A, but a hydrophobic state of the silicon surface 412 of the substrate 404, as shown in FIG. 5C. The hydrophobic state adversely affects the bonding energy of the subsequent surface bonding process. Accordingly, a surface activation process may be performed at step 310 to active the surfaces 410, 412 of the substrates 402, 404 to convert and ensure both the surfaces of the first and second substrates 402, 404 are in hydrophilic states. The hydrophilic state promotes bonding energy between the substrates 402, 404.

The surface activation process performed at step 310 actives the surfaces 410′, 412′ of the substrates 402, 404, as shown in FIG. 4E, forming oxidized layer on the substrate surface 410′, 412′. The surface activation process includes providing an oxygen gas into a plasma immersion ion implantation reactor, which is ionized by RF power to provide oxygen ions. The oxygen ions oxidize the surfaces of the substrates 402, 404 to form oxidized silicon layer 410′, 412′ on the substrates 402, 404. The hydrophobic state of the substrate 404 is now converted into in hydrophilic state having silanol terminated group, e.g., Si—OH bonds, as shown in FIG. 5C. The oxidized silicon layer 410′, 412′ provides a hydrophilic surface promoting the bonding energy between the substrates 402, 404.

At step 312, the first substrate 402 is flipped over and bonded to the second substrate 404, as shown in FIG. 4F. Van der Wals forces cause the two surfaces 410′ and 412′ to adhere. FIGS. 5D-5F depict the bonding mechanism occurred between the substrate interface. As the hydrophilic state of the substrates 402, 404 creates a silanol (Si—OH) group terminated on the surfaces 410′, 412′, the hydrogen atoms on each substrate surfaces are attached by electronegative atoms, such as oxygen atoms, as shown in FIG. 5D. The oxygen atoms provided by the silanol group act as hydrogen-bond donors while the hydrogen atoms act as hydrogen-bond acceptors, creating an attractive intermolecular force, e.g., hydrogen bond, between two substrate surfaces, as shown in FIG. 5E. Thermal energy, provided by heating the substrates 402, 404 to a predetermined temperature, may be utilized to promote the surface adhesion by driving out and evaporating the H₂O molecular formed on the interface, as shown in FIG. 5F, thereby creating a strong bonding between the surfaces 410′, 412′. In one embodiment, the substrates 402, 404 are heated to temperature greater than about 800 degrees Celsius.

Furthermore, the thermal energy causes the Van der Wals forces to be replaced by atomic bonds formed between facing lattice sites in the oxidized silicon layer surfaces 410′, 412′. A greater proportion of the lattice atomic sites in each surface 410′, 412′ are available for atomic bonding with lattice sites in the other surface created by the plasma immersion ion implantation process at step 308. As a result, the bonding force between the substrates 402, 404 is increased over conventional techniques.

At step 314, the first substrate 402 is separated along the cleavage plane 408, leaving a thin portion 414 of the first substrate 402 bonded to the second substrate 404, as shown in FIG. 4G. The thin portion 414 includes a silicon layer disposed on the silicon oxide layer 406 on the silicon substrate 404.

At step 316, the stack film of the silicon layer 414 from the first substrate 404, and the silicon oxide layer 404 on the second substrate 404 is utilized to form SOI substrate.

As the split surface 418 formed on the second surface 404 may becomes rough after cleavage or from the ion bombardment damaged caused at step 306, a surface smoothing implant process may be performed to smooth and recrystallize the surface of the silicon layer 414. The surface smoothing implant process may be performed by implanting ions at low energy and relatively high momentum, using low energy heavy ions, such as Xe or Ar. The surface smoothing implant process may be performed at the reactor 200 described in FIGS. 2A-B or other suitable reactor. The surface smoothing implant process may also be performed by any suitable process.

Thus, methods for promoting interface bonding energy are provided. The improved method that advantageously modifies the substrate surface properties and removes the surface contaminants and particles, thereby activating and promoting the bonding force between substrates and facilitating fabrication of robust SOI structures.

Although the methods for cleaning substrate interface described in the present application is illustrated for forming SOI, it is contemplated that the methods may be utilized to clean different substrate materials, such as GaN, GeSi, Si, SiO₂, InP, GaAs, glass, plastic, metal and the like.

While the foregoing is directed to embodiments of the present invention, other and further embodiments of the invention may be devised without departing from the basic scope thereof, and the scope thereof is determined by the claims that follow.

What is claimed:

1. A method for cleaning substrate surface, comprising:
providing a first substrate and a second substrate, wherein the first substrate has a silicon oxide layer formed thereon and a cleavage plane defined therein;
performing a wet cleaning process on a surface of the silicon oxide layer on the first substrate and a surface of the second substrate; and
bonding the cleaned silicon oxide layer to the cleaned surface of the second substrate.

2. The method of claim 1, wherein the step of performing the wet cleaning process further comprises:
exposing the surfaces of the silicon oxide layer on the first substrate and the second substrate to a first solution including NH₄OH, H₂O₂ and H₂O.

3. The method of claim 2, wherein the first solution is maintained at a pH level between about 9 and about 12.

4. The method of claim 2, wherein the first solution further includes a chelating agent.

5. The method of claim 4, wherein the chelating agent is selected from a group consisting of polyacrylates, carbonates, phosphonates, gluconates, ethylenediaminetetraacetic acid (EDTA), N,N′-bis(2-hydroxyphenyl)ethylenediiminodiacetic acid (HPED), triethylenetetranitrilohexaaxtic (TTHA), desferriferioxamin B, N,N′,N″-tris[2-(N-hydroxycarbonyl)ethyl]-1,3,5-benzenetricarboxamide (BAMTPH) and ethylenediaminediorthohydroxyphenylacetic acid (EDDHA).

6. The method of claim 2, wherein the first solution further includes a surfactant.

7. The method of claim 6, wherein the surfactant is selected from a group consisting of polyoxyethylene butylphenyl ether, polyoxyethylene alkylphenyl sulfate, or MCX-SD2000 solution.

8. The method of claim 2, wherein the step of exposing the surfaces to the first solution further comprises:
exposing the surfaces of the first and the second substrates to a second solution including HCl, H₂O₂ and H₂O.

9. The method of claim 1, wherein the step of performing the wet cleaning process further comprises:
exposing the top and bottom surface of the first and the second substrate to different solutions.

10. The method of claim 9, wherein the step of exposing the substrate to different solutions further comprises:
exposing the bottom surface of the first and the second substrates by a third solution.

11. The method of claim 10, wherein the third solution is de-ionized water.

12. The method of claim 10, wherein the third solution is the first solution.

13. The method of claim 1, wherein the step of performing the wet cleaning process further comprises:
disposing the substrates on a substrate support in a substrate cleaning tool;
simultaneously cleaning a top surface of the substrates by an exposure to a first solution and a bottom side of the substrates by an exposure to a third solution.

14. The method of claim 8, wherein the step of exposing the substrate to the second solution further comprises:
rinsing the substrates prior to cleaning the substrates by the second solution.

15. The method of claim 1, wherein the step of performing the wet cleaning process further comprises:
removing the particles and/or contaminants from the substrates.

16. The method of claim 1, wherein the step of performing the wet cleaning process further comprises:
oxidizing the surfaces of the first and the second substrate; and
altering the surfaces of the first and the second substrate into hydrophilic state.

17. The method of claim 1, wherein the step of bonding the cleaned surface further comprises:
heating the bonded substrates to a temperature greater than about 800 degrees Celsius.

18. The method of claim 1, further comprising:
splitting the first substrate along the cleavage plane.

19. The method of claim 1, further comprising:
forming an silicon on insulator (SOI) structure on the second substrate.

20. A method for promoting interface bonding energy, comprising:
providing a first substrate and a second substrate, wherein the first substrate has a silicon oxide layer formed thereon and a cleavage plane defined therein;
removing particles and/or contaminants from a surface of the first substrate and a surface of the second substrate by a wet cleaning process;
activating the cleaned surfaces of the first and the second substrate; and
bonding the silicon oxide layer disposed on the first substrate to the activated surface of the second substrate.

21. The method of claim 20, wherein the step of removing the particles and/or contaminants further comprises:
cleaning the surfaces of the substrates by exposure to a first solution including NH₄OH, H₂O₂ and H₂O.

22. The method of claim 20, wherein the step of removing the particles and/or contaminants further comprises:
cleaning the surfaces of the substrates by exposure to a second solution including HCl, H₂O₂ and H₂O.

23. The method of claim 21, wherein the first solution further includes a chelating agent.

24. The method of claim 21, wherein the first solution further includes a surfactant.

25. A method for promoting interface bonding energy, comprising:
providing a first substrate and a second substrate, wherein the first substrate has a silicon oxide layer formed thereon and a cleavage plane defined therein;
performing a wet cleaning process on a surface of the silicon oxide layer and a surface of the second substrate by exposure to a solution including NH₄OH, H₂O₂ and H₂O;
activating the cleaned surfaces of the first and the second substrate;
bonding the silicon oxide surface to the activated surface of the second substrate; and
splitting the first substrate along the cleavage plane.

26. The method of claim 25, wherein the solution further includes a chelating agent.

27. The method of claim 25, wherein the solution further includes a surfactant.
